(19) United States
(12) Patent Application Publication
(10) Pub. No.: US 2024/0222305 A1
(43) Pub. Date: Jul. 4, 2024

(54) SEMICONDUCTOR PACKAGE STRUCTURE AND METHOD FOR FABRICATING THE SAME

(71) Applicant: Industrial Technology Research Institute, Hsinchu (TW)

(72) Inventor: Yu-Wei HUANG, Chiayi City (TW)

(73) Assignee: Industrial Technology Research Institute, Hsinchu (TW)

(21) Appl. No.: 18/166,517

(22) Filed: Feb. 9, 2023

(30) Foreign Application Priority Data
Jan. 3, 2023 (TW) 112100022

(51) Int. Cl. H01L 23/00; H01L 25/065

(52) U.S. Cl. CPC H01L 24/16; H01L 24/11; H01L 24/24; H01L 24/73; H01L 25/0655; H01L 2224/1132; H01L 2224/11849; H01L 2224/16225; H01L 2224/16501; H01L 2224/24227; H01L 2224/73209; H01L 2924/1517

(57) ABSTRACT

A semiconductor package structure is provided. The semiconductor package structure includes a carrier, a circuit layer, and a plurality of contacts electrically connecting the circuit layer to the carrier. Each contact includes a metal portion and an insulating portion. The insulating portion surrounds the metal portion. A gap is formed between the contacts.

### CROSS-REFERENCE TO RELATED APPLICATION

This application claims priority of Taiwan Patent Application No. 112100022, filed on Jan. 3, 2023, the entirety of which is incorporated by reference herein.

### FIELD OF THE INVENTION

The disclosure relates to a semiconductor package structure, and relates to a semiconductor package structure with contacts composed of metal and insulating material.

### BACKGROUND

In the semiconductor manufacturing process, the different materials that make up fine-line thin-film layers, solder balls, printed circuit boards (PCB), and underfill will generally have different thermal-expansion coefficients under a temperature load. As a result, different thermal deformations will be generated between each structure, resulting in structural warping and deformation. This deformation can limit the subsequent applications in which the final product may be used, as well as reducing its reliability.

### BRIEF SUMMARY OF THE INVENTION

In accordance with one embodiment of the disclosure, a semiconductor package structure is provided. The semiconductor package structure includes a carrier, a circuit layer, and a plurality of contacts electrically connecting the circuit layer to the carrier. Each contact includes a metal portion and an insulating portion. The insulating portion surrounds the metal portion. A gap is formed between the contacts.

In accordance with one embodiment of the disclosure, a method for fabricating a semiconductor package structure is provided. The fabricating method includes the following steps. A carrier with a first metal pad disposed thereon is provided. A substrate with a circuit layer and a second metal pad disposed thereon in order is provided. A contact material is formed on the first metal pad of the carrier. The circuit layer is bonded to the carrier through the second metal pad, the contact material, and the first metal pad. The substrate is removed.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a cross-sectional view of a semiconductor package structure in accordance with one embodiment of the disclosure;

FIG. 2 shows a cross-sectional view of a semiconductor package structure in accordance with one embodiment of the disclosure;

FIG. 3 shows a cross-sectional view of a semiconductor package structure in accordance with one embodiment of the disclosure;

FIG. 4 shows a cross-sectional view of a semiconductor package structure in accordance with one embodiment of the disclosure; and

FIGS. 5A-5F show cross-sectional views of a method for fabricating a semiconductor package structure in accordance with one embodiment of the disclosure.

### DETAILED DESCRIPTION OF THE INVENTION

Various embodiments or examples are provided in the following description to implement different features of the present disclosure. The elements and arrangement described in the following specific examples are merely provided for introducing the present disclosure and serve as examples without limiting the scope of the present disclosure. For example, when a first component is referred to as “on a second component”, it may directly contact the second component, or there may be other components in between, and the first component and the second component do not come in direct contact with one another.

It should be understood that additional operations may be provided before, during, and/or after the described method. In accordance with some embodiments, some of the stages (or steps) described below may be replaced or omitted.

In addition, in this specification, spatial terms may be used, such as “below”, “lower”, “above”, “higher”, “on” and similar terms, for briefly describing the relationship between an element relative to another element in the figures. Besides the directions illustrated in the figures, the devices may be used or operated in different directions. When the device is turned to different directions (such as rotated 45 degrees or other directions), the spatially related adjectives used in it will also be interpreted according to the turned position. In addition, in this specification, expressions such as “first material layer disposed above/on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer. In some embodiments of the present disclosure, terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Herein, the terms “about”, “around” and “substantially” typically mean a value is in a range of +/−15% of a stated value, typically a range of +/−10% of the stated value, typically a range of +/−5% of the stated value, typically a range of +/−3% of the stated value, typically a range of +/−2% of the stated value, typically a range of +/−1% of the stated value, or typically a range of +/−0.5% of the stated value.

It should be understood that, although the terms “first”, “second”, “third”, etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, portion or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

The disclosure is to reduce the warpage of heterogeneous integrated structures and reduce the stress in those structures. The disclosure provides a semiconductor package structure, which utilizes a design that incorporates a metal-insulating material composite contact arranged between the circuit layer and the carrier to simultaneously reduce warpage and stress in the heterogeneous integrated structure, and improve the reliability and durability of the final product.

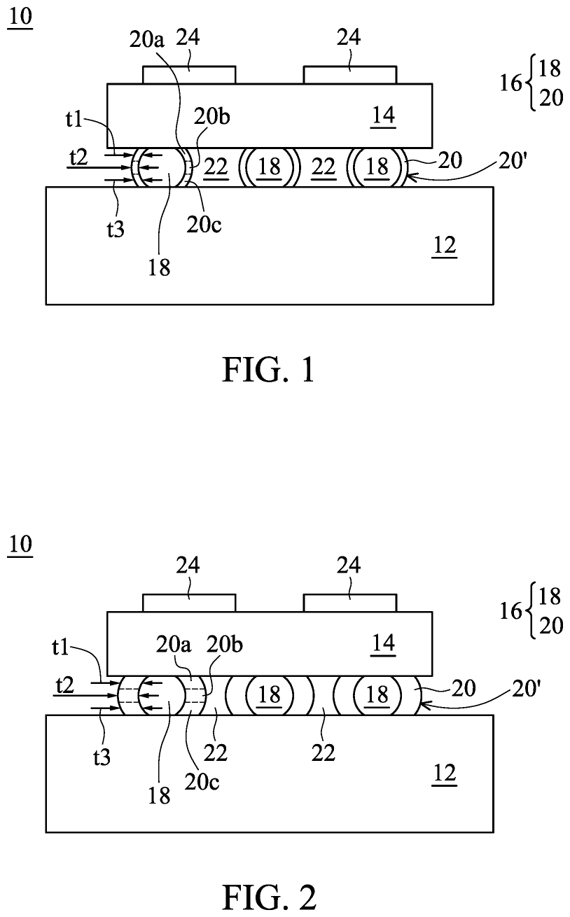

Referring to FIG. 1, in accordance with one embodiment of the disclosure, a semiconductor package structure 10 is provided. FIG. 1 shows a cross-sectional view of the semiconductor package structure 10.

As shown in FIG. 1, the semiconductor package structure 10 includes a carrier 12, a circuit layer 14, and a plurality of contacts 16. The contacts 16 are electrically connected with the circuit layer 14 and the carrier 12. Each contact 16 includes a metal portion 18 and an insulating portion 20. The insulating portion 20 surrounds the metal portion 18. A gap 22 is formed between adjacent contacts 16. That is, the insulating portion 20 of each contact 16 is located at the periphery of its own metal portion 18, and the insulating portions 20 of the adjacent contacts 16 are separated from each other by the gap 22 without substantial contact, but the disclosure is not limited thereto, and other suitable extended states of the insulating portions are also applicable to the disclosure. For example, in the presence of the gap 22, the insulating portions 20 of the adjacent contacts 16 can extend outward from the periphery of the metal portion 18 itself, so that the insulating portions 20 of the adjacent contacts 16 form a state of partial contact with each other.

In one embodiment, the carrier 12 may include a substrate or a printed circuit board (PCB), or the like. In one embodiment, when the carrier 12 is a substrate, it may include a semiconductor substrate, a ceramic substrate, a glass substrate, a polymer substrate, or a combination of the aforementioned types of substrates, but the disclosure is not limited thereto, and other suitable substrate materials are also applicable to the disclosure. In one embodiment, the material of the aforementioned semiconductor substrate may include elemental semiconductors (for example, silicon and/or germanium), compound semiconductors (for example, gallium nitride, silicon carbide, gallium arsenide, gallium phosphide, indium phosphide, indium arsenide, gallium antimonide, indium antimonide, lithium tantalum oxide (LiTaO₃) and/or lithium niobium oxide (LiNbO₃)), alloy semiconductors (for example, silicon-germanium alloy, phosphorus-arsenic-gallium alloy, arsenic-aluminum-indium alloy, arsenic-aluminum-gallium alloy, arsenic-gallium-indium alloy, phosphorous-gallium-indium alloy, and/or arsenic-phosphorous-gallium-indium alloy), or a combination of the above semiconductor materials, but the disclosure is not limited thereto, and other suitable semiconductor materials are also applicable to the disclosure.

In one embodiment, the carrier 12 may be a composite substrate including additional elements (for simplicity, not shown), such as thin-film transistors (TFTs), complementary metal oxide semiconductors (CMOSs), driving elements, conductive elements, other similar elements, or a combination of the aforementioned various elements, but the disclosure is not limited thereto, and other suitable elements are also applicable to the disclosure. In one embodiment, the aforementioned conductive elements may include cobalt, ruthenium, aluminum, tungsten, copper, titanium, tantalum, silver, gold, platinum, nickel, zinc, chromium, molybdenum, niobium, other similar conductive materials, an alloy combination of the aforementioned various conductive materials, or multiple films of the aforementioned various conductive materials, but the disclosure is not limited thereto, and other suitable conductive materials are also applicable to the disclosure. These elements provide circuits to connect to the elements on the substrate.

In one embodiment, when the carrier 12 is a printed circuit board (PCB), its surface includes a metal-wire layer (for simplicity, not shown) electrically connected to the circuit layer 14 through the contacts 16.

In one embodiment, the line width or the line spacing of the circuit layer 14 is less than 35 μm. In one embodiment, the line width or the line spacing of the circuit layer 14 is less than 15 μm. In one embodiment, the circuit layer 14 may include a redistribution layer (RDL). In one embodiment, the aforementioned redistribution layer (RDL) may include multiple insulating layers and conductive layers stacked alternately, and may further include, for example, thin-film transistors, resistive elements, capacitive elements, or inductive elements, but the disclosure is not limited thereto, and other suitable elements are also included in the redistribution layer (RDL).

In one embodiment, the metal portion 18 of the contact 16 may include tin, silver, copper, nickel, germanium, lead, antimony, bismuth, cadmium, gold, indium, aluminum, arsenic, iron, zinc, or an alloy combination containing the above various metal materials, but the disclosure is not limited thereto, and other suitable metal materials are also applicable to the disclosure. In one embodiment, the appearance profile of the metal portion 18 of the contact 16 may be spherical, but the disclosure is not limited thereto, and other suitable appearance profiles are also applicable to the disclosure. In one embodiment, when the metal portion 18 of the contact 16 is spherical, its particle size is in a range from about 50 μm to about 500 μm, but the disclosure is not limited thereto, and other suitable particle sizes are also applicable to the disclosure. In one embodiment, the insulating portion 20 of the contact 16 may include organic insulating materials, such as epoxy resin, polyimide (PI), benzocyclobutene (BCB), or a combination of the above various organic insulating materials, but the disclosure is not limited thereto, and other suitable organic insulating materials are also applicable to the disclosure.

In FIG. 1, the insulating portion 20 of the contact 16 includes a first portion 20a, a second portion 20b, and a third portion 20c. The first portion 20a is in contact with the circuit layer 14. The third portion 20c is in contact with the carrier 12. The second portion 20b is located between the first portion 20a and the third portion 20c. In one embodiment, the thickness t1 of the first portion 20a, the thickness t2 of the second portion 20b, and the thickness t3 of the third portion 20c of the insulating portion 20 are about the same or may be different. As shown in FIG. 1, when the metal portion 18 of the contact 16 is spherical, the sidewall 20′ of the insulating portion 20 may present, for example, a state of protruding outward. In one embodiment, the thickness t2 of the second portion 20b of the insulating portion 20 is in a range from about 0.1 μm to about 100 μm. In the embodiment shown in FIG. 1, the insulating portion 20 of each contact 16 is located on the periphery of its own metal portion 18. That is, the insulating portions 20 of the adjacent contacts 16 are separated from each other by the gap 22 and are not substantially in contact with each other, or it is also possible that the insulating portions 20 of the adjacent contacts 16 are in contact with each other via the gap 22.

In one embodiment, the semiconductor package structure 10 of the disclosure further includes a chip 24 disposed on the circuit layer 14 and electrically connected to the circuit layer 14. The chip 24 may be electrically connected to the carrier 12 through the circuit layer 14 and the contacts 16.

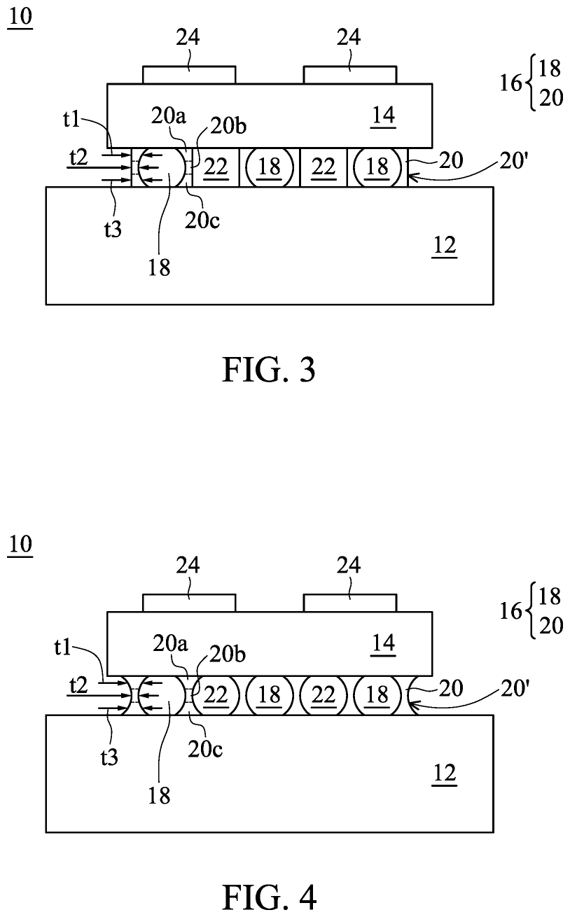

Referring to FIG. 2, in accordance with one embodiment of the disclosure, a semiconductor package structure 10 is provided. FIG. 2 shows a cross-sectional view of the semiconductor package structure 10.

As shown in FIG. 2, the semiconductor package structure 10 includes a carrier 12, a circuit layer 14, and a plurality of contacts 16. The contacts 16 are electrically connected with the circuit layer 14 and the carrier 12. Each contact 16 includes a metal portion 18 and an insulating portion 20. The insulating portion 20 surrounds the metal portion 18. A gap 22 is formed between adjacent contacts 16. That is, the insulating portion 20 of each contact 16 is located at the periphery of its own metal portion 18, and the insulating portions 20 of the adjacent contacts 16 are separated from each other by the gap 22 without substantial contact, but the disclosure is not limited thereto, and other suitable extended states of the insulating portions are also applicable to the disclosure. For example, in the presence of the gap 22, the insulating portions 20 of the adjacent contacts 16 can extend outward from the periphery of the metal portion 18 itself, so that the insulating portions 20 of the adjacent contacts 16 form a state of partial contact with each other.

In one embodiment, the carrier 12 may include a substrate or a printed circuit board (PCB), or the like. In one embodiment, when the carrier 12 is a substrate, it may include a semiconductor substrate, a ceramic substrate, a glass substrate, a polymer substrate, or a combination of the aforementioned types of substrates, but the disclosure is not limited thereto, and other suitable substrate materials are also applicable to the disclosure. In one embodiment, the material of the aforementioned semiconductor substrate may include elemental semiconductors (for example, silicon and/or germanium), compound semiconductors (for example, gallium nitride, silicon carbide, gallium arsenide, gallium phosphide, indium phosphide, indium arsenide, gallium antimonide, indium antimonide, lithium tantalum oxide (LiTaO₃) and/or lithium niobium oxide (LiNbO₃)), alloy semiconductors (for example, silicon-germanium alloy, phosphorus-arsenic-gallium alloy, arsenic-aluminum-indium alloy, arsenic-aluminum-gallium alloy, arsenic-gallium-indium alloy, phosphorous-gallium-indium alloy, and/or arsenic-phosphorous-gallium-indium alloy), or a combination of the above semiconductor materials, but the disclosure is not limited thereto, and other suitable semiconductor materials are also applicable to the disclosure.

In one embodiment, the carrier 12 may be a composite substrate including additional elements (for simplicity, not shown), such as thin-film transistors (TFTs), complementary metal oxide semiconductors (CMOSs), driving elements, conductive elements, other similar elements, or a combination of the aforementioned various elements, but the disclosure is not limited thereto, and other suitable elements are also applicable to the disclosure. In one embodiment, the aforementioned conductive elements may include cobalt, ruthenium, aluminum, tungsten, copper, titanium, tantalum, silver, gold, platinum, nickel, zinc, chromium, molybdenum, niobium, other similar conductive materials, an alloy combination of the aforementioned various conductive materials, or multiple films of the aforementioned various conductive materials, but the disclosure is not limited thereto, and other suitable conductive materials are also applicable to the disclosure. These elements provide circuits to connect to the elements on the substrate.

In one embodiment, when the carrier 12 is a printed circuit board (PCB), its surface includes a metal-wire layer (for simplicity, not shown) electrically connected to the circuit layer 14 through the contacts 16.

In one embodiment, the line width or the line spacing of the circuit layer 14 is less than 35 μm. In one embodiment, the line width or the line spacing of the circuit layer 14 is less than 15 μm. In one embodiment, the circuit layer 14 may include a redistribution layer (RDL). In one embodiment, the aforementioned redistribution layer (RDL) may include multiple insulating layers and conductive layers stacked alternately, and may further include, for example, thin-film transistors, resistive elements, capacitive elements, or inductive elements, but the disclosure is not limited thereto, and other suitable elements are also included in the redistribution layer (RDL).

In one embodiment, the metal portion 18 of the contact 16 may include tin, silver, copper, nickel, germanium, lead, antimony, bismuth, cadmium, gold, indium, aluminum, arsenic, iron, zinc, or an alloy combination containing the above various metal materials, but the disclosure is not limited thereto, and other suitable metal materials are also applicable to the disclosure. In one embodiment, the appearance profile of the metal portion 18 of the contact 16 may be spherical, but the disclosure is not limited thereto, and other suitable appearance profiles are also applicable to the disclosure. In one embodiment, when the metal portion 18 of the contact 16 is spherical, its particle size is in a range from about 50 μm to about 500 μm, but the disclosure is not limited thereto, and other suitable particle sizes are also applicable to the disclosure. In one embodiment, the insulating portion 20 of the contact 16 may include organic insulating materials, such as epoxy resin, polyimide (PI), benzocyclobutene (BCB), or a combination of the above various organic insulating materials, but the disclosure is not limited thereto, and other suitable organic insulating materials are also applicable to the disclosure.

In FIG. 2, the insulating portion 20 of the contact 16 includes a first portion 20a, a second portion 20b, and a third portion 20c. The first portion 20a is in contact with the circuit layer 14. The third portion 20c is in contact with the carrier 12. The second portion 20b is located between the first portion 20a and the third portion 20c. In one embodiment, the thickness t1 of the first portion 20a, the thickness t2 of the second portion 20b, and the thickness t3 of the third portion 20c of the insulating portion 20 are about the same or may be different. As shown in FIG. 2, when the metal portion 18 of the contact 16 is spherical, the sidewall 20′ of the insulating portion 20 may present, for example, a state of protruding outward. In one embodiment, the thickness t2 of the second portion 20b of the insulating portion 20 is in a range from about 0.1 μm to about 100 μm. In the embodiment shown in FIG. 2, the insulating portion 20 of each contact 16 is located on the periphery of its own metal portion 18. That is, the insulating portions 20 of the adjacent contacts 16 are separated from each other by the gap 22 and are not substantially in contact with each other, or the insulating portions 20 of the adjacent contacts 16 are in contact with each other via the gap 22. The difference between the embodiment shown in FIG. 2 and the embodiment shown in FIG. 1 is that, in FIG. 2, the thickness t2 of the second portion 20b of the insulating portion 20 is approximately greater than the thickness t2 of the second portion 20b of the insulating portion 20 shown in FIG. 1.

In one embodiment, the semiconductor package structure 10 of the disclosure further includes a chip 24 disposed on the circuit layer 14 and electrically connected to the circuit layer 14. The chip 24 may be electrically connected to the carrier 12 through the circuit layer 14 and the contacts 16.

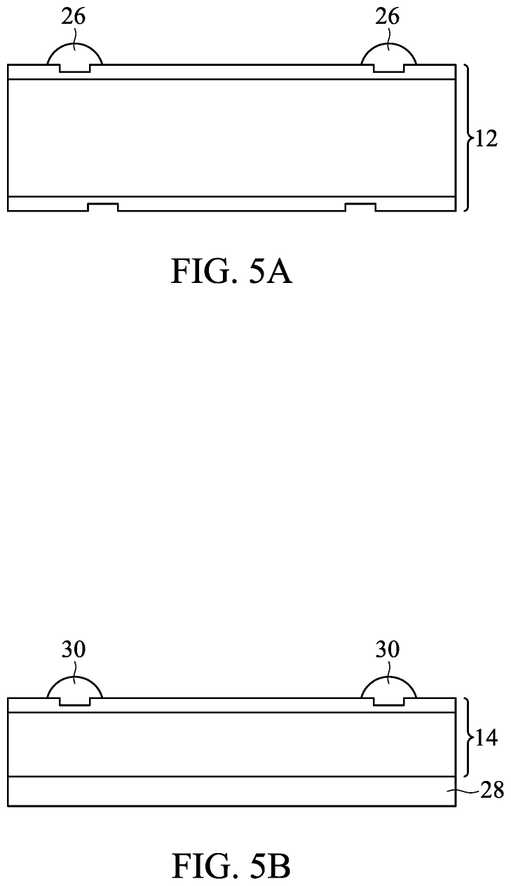

Referring to FIG. 3, in accordance with one embodiment of the disclosure, a semiconductor package structure 10 is provided. FIG. 3 shows a cross-sectional view of the semiconductor package structure 10.

As shown in FIG. 3, the semiconductor package structure 10 includes a carrier 12, a circuit layer 14, and a plurality of contacts 16. The contacts 16 are electrically connected with the circuit layer 14 and the carrier 12. Each contact 16 includes a metal portion 18 and an insulating portion 20. The insulating portion 20 surrounds the metal portion 18. A gap 22 is formed between adjacent contacts 16. That is, the insulating portion 20 of each contact 16 is located at the periphery of its own metal portion 18. The insulating portions 20 of the adjacent contacts 16 are separated from each other by the gap 22 without substantial contact, or the insulating portions 20 of the adjacent contacts 16 are in contact with each other via the gap 22, but the disclosure is not limited thereto, and other suitable extended states of the insulating portions are also applicable to the disclosure. For example, in the presence of the gap 22, the insulating portions 20 of the adjacent contacts 16 can extend outward from the periphery of the metal portion 18 itself, so that the insulating portions 20 of the adjacent contacts 16 form a state of partial contact with each other.

In one embodiment, the carrier 12 may include a substrate or a printed circuit board (PCB), or the like. In one embodiment, when the carrier 12 is a substrate, it may include a semiconductor substrate, a ceramic substrate, a glass substrate, a polymer substrate, or a combination of the aforementioned types of substrates, but the disclosure is not limited thereto, and other suitable substrate materials are also applicable to the disclosure. In one embodiment, the material of the aforementioned semiconductor substrate may include elemental semiconductors (for example, silicon and/or germanium), compound semiconductors (for example, gallium nitride, silicon carbide, gallium arsenide, gallium phosphide, indium phosphide, indium arsenide, gallium antimonide, indium antimonide, lithium tantalum oxide (LiTaO₃) and/or lithium niobium oxide (LiNbO₃)), alloy semiconductors (for example, silicon-germanium alloy, phosphorus-arsenic-gallium alloy, arsenic-aluminum-indium alloy, arsenic-aluminum-gallium alloy, arsenic-gallium-indium alloy, phosphorous-gallium-indium alloy, and/or arsenic-phosphorous-gallium-indium alloy), or a combination of the above semiconductor materials, but the disclosure is not limited thereto, and other suitable semiconductor materials are also applicable to the disclosure.

In one embodiment, the carrier 12 may be a composite substrate including additional elements (for simplicity, not shown), such as thin-film transistors (TFTs), complementary metal oxide semiconductors (CMOSs), driving elements, conductive elements, other similar elements, or a combination of the aforementioned various elements, but the disclosure is not limited thereto, and other suitable elements are also applicable to the disclosure. In one embodiment, the aforementioned conductive elements may include cobalt, ruthenium, aluminum, tungsten, copper, titanium, tantalum, silver, gold, platinum, nickel, zinc, chromium, molybdenum, niobium, other similar conductive materials, an alloy combination of the aforementioned various conductive materials, or multiple films of the aforementioned various conductive materials, but the disclosure is not limited thereto, and other suitable conductive materials are also applicable to the disclosure. These elements provide circuits to connect to the elements on the substrate.

In one embodiment, when the carrier 12 is a printed circuit board (PCB), its surface includes a metal-wire layer (for simplicity, not shown) electrically connected to the circuit layer 14 through the contacts 16.

In one embodiment, the line width or the line spacing of the circuit layer 14 is less than 35 μm. In one embodiment, the line width or the line spacing of the circuit layer 14 is less than 15 μm. In one embodiment, the circuit layer 14 may include a redistribution layer (RDL). In one embodiment, the aforementioned redistribution layer (RDL) may include multiple insulating layers and conductive layers stacked alternately, and may further include, for example, thin-film transistors, resistive elements, capacitive elements, or inductive elements, but the disclosure is not limited thereto, and other suitable elements are also included in the redistribution layer (RDL).

In one embodiment, the metal portion 18 of the contact 16 may include tin, silver, copper, nickel, germanium, lead, antimony, bismuth, cadmium, gold, indium, aluminum, arsenic, iron, zinc, or an alloy combination containing the above various metal materials, but the disclosure is not limited thereto, and other suitable metal materials are also applicable to the disclosure. In one embodiment, the appearance profile of the metal portion 18 of the contact 16 may be spherical, but the disclosure is not limited thereto, and other suitable appearance profiles are also applicable to the disclosure. In one embodiment, when the metal portion 18 of the contact 16 is spherical, its particle size is in a range from about 50 μm to about 500 μm, but the disclosure is not limited thereto, and other suitable particle sizes are also applicable to the disclosure. In one embodiment, the insulating portion 20 of the contact 16 may include organic insulating materials, such as epoxy resin, polyimide (PI), benzocyclobutene (BCB), or a combination of the above various organic insulating materials, but the disclosure is not limited thereto, and other suitable organic insulating materials are also applicable to the disclosure.

In FIG. 3, the insulating portion 20 of the contact 16 includes a first portion 20a, a second portion 20b, and a third portion 20c. The first portion 20a is in contact with the circuit layer 14. The third portion 20c is in contact with the carrier 12. The second portion 20b is located between the first portion 20a and the third portion 20c. In one embodiment, the thickness t1 of the first portion 20a, the thickness t2 of the second portion 20b, and the thickness t3 of the third portion 20c of the insulating portion 20 are not all the same. For example, the thickness t1 of the first portion 20a is about the same as or different from the thickness t3 of the third portion 20c, and the thickness t1 of the first portion 20a is approximately greater than the thickness t2 of the second portion 20b. As shown in FIG. 3, when the metal portion 18 of the contact 16 is spherical, the sidewall 20′ of the insulating portion 20 may present, for example, a profile approximately perpendicular to the carrier 12 and the circuit layer 14. In one embodiment, the thickness t2 of the second portion 20b of the insulating portion 20 is in a range from about 0.1 μm to about 100 μm. In the embodiment shown in FIG. 3, the insulating portion 20 of each contact 16 is located on the periphery of its own metal portion 18. That is, the insulating portions 20 of the adjacent contacts 16 are separated from each other by the gap 22 and are not substantially in contact with each other, or the insulating portions 20 of the adjacent contacts 16 are in contact with each other via the gap 22.

In one embodiment, the semiconductor package structure 10 of the disclosure further includes a chip 24 disposed on the circuit layer 14 and electrically connected to the circuit layer 14. The chip 24 may be electrically connected to the carrier 12 through the circuit layer 14 and the contacts 16.

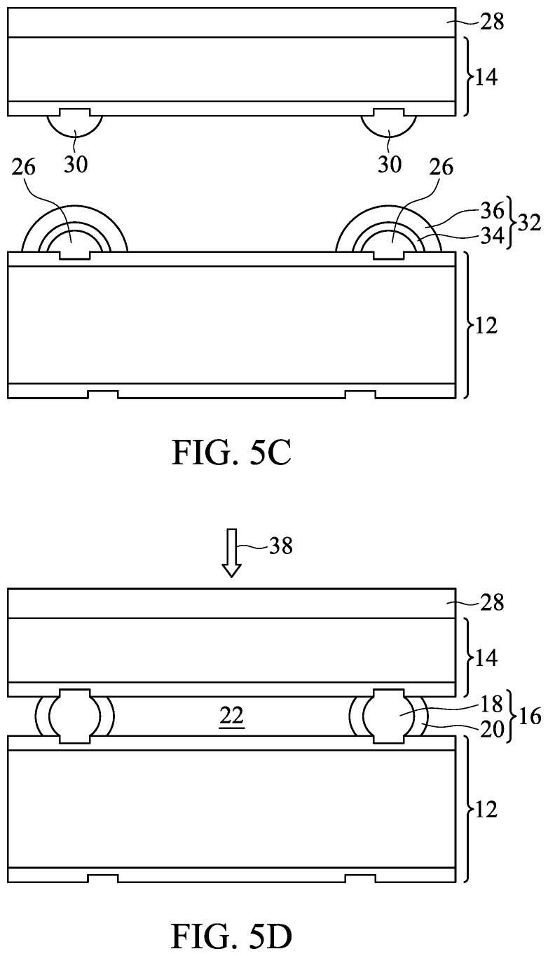

Referring to FIG. 4, in accordance with one embodiment of the disclosure, a semiconductor package structure 10 is provided. FIG. 4 shows a cross-sectional view of the semiconductor package structure 10.

As shown in FIG. 4, the semiconductor package structure 10 includes a carrier 12, a circuit layer 14, and a plurality of contacts 16. The contacts 16 are electrically connected with the circuit layer 14 and the carrier 12. Each contact 16 includes a metal portion 18 and an insulating portion 20. The insulating portion 20 surrounds the metal portion 18. A gap 22 is formed between adjacent contacts 16. That is, the insulating portion 20 of each contact 16 is located at the periphery of its own metal portion 18. The insulating portions 20 of the adjacent contacts 16 are separated from each other by the gap 22 without substantial contact, but the disclosure is not limited thereto, and other suitable extended states of the insulating portions are also applicable to the disclosure. For example, in the presence of the gap 22, the insulating portions 20 of the adjacent contacts 16 can extend outward from the periphery of the metal portion 18 itself, so that the insulating portions 20 of the adjacent contacts 16 form a state of partial contact with each other.

In one embodiment, the carrier 12 may include a substrate or a printed circuit board (PCB), or the like. In one embodiment, when the carrier 12 is a substrate, it may include a semiconductor substrate, a ceramic substrate, a glass substrate, a polymer substrate, or a combination of the aforementioned types of substrates, but the disclosure is not limited thereto, and other suitable substrate materials are also applicable to the disclosure. In one embodiment, the material of the aforementioned semiconductor substrate may include elemental semiconductors (for example, silicon and/or germanium), compound semiconductors (for example, gallium nitride, silicon carbide, gallium arsenide, gallium phosphide, indium phosphide, indium arsenide, gallium antimonide, indium antimonide, lithium tantalum oxide (LiTaO₃) and/or lithium niobium oxide (LiNbO₃)), alloy semiconductors (for example, silicon-germanium alloy, phosphorus-arsenic-gallium alloy, arsenic-aluminum-indium alloy, arsenic-aluminum-gallium alloy, arsenic-gallium-indium alloy, phosphorous-gallium-indium alloy, and/or arsenic-phosphorous-gallium-indium alloy), or a combination of the above semiconductor materials, but the disclosure is not limited thereto, and other suitable semiconductor materials are also applicable to the disclosure.

In one embodiment, the carrier 12 may be a composite substrate including additional elements (for simplicity, not shown), such as thin-film transistors (TFTs), complementary metal oxide semiconductors (CMOSs), driving elements, conductive elements, other similar elements, or a combination of the aforementioned various elements, but the disclosure is not limited thereto, and other suitable elements are also applicable to the disclosure. In one embodiment, the aforementioned conductive elements may include cobalt, ruthenium, aluminum, tungsten, copper, titanium, tantalum, silver, gold, platinum, nickel, zinc, chromium, molybdenum, niobium, other similar conductive materials, an alloy combination of the aforementioned various conductive materials, or multiple films of the aforementioned various conductive materials, but the disclosure is not limited thereto, and other suitable conductive materials are also applicable to the disclosure. These elements provide circuits to connect to the elements on the substrate.

In one embodiment, when the carrier 12 is a printed circuit board (PCB), its surface includes a metal-wire layer (for simplicity, not shown) electrically connected to the circuit layer 14 through the contacts 16.

In one embodiment, the line width or the line spacing of the circuit layer 14 is less than 35 μm. In one embodiment, the line width or the line spacing of the circuit layer 14 is less than 15 μm. In one embodiment, the circuit layer 14 may include a redistribution layer (RDL). In one embodiment, the aforementioned redistribution layer (RDL) may include multiple insulating layers and conductive layers stacked alternately, and may further include, for example, thin-film transistors, resistive elements, capacitive elements, or inductive elements, but the disclosure is not limited thereto, and other suitable elements are also included in the redistribution layer (RDL).

In one embodiment, the metal portion 18 of the contact 16 may include tin, silver, copper, nickel, germanium, lead, antimony, bismuth, cadmium, gold, indium, aluminum, arsenic, iron, zinc, or an alloy combination containing the above various metal materials, but the disclosure is not limited thereto, and other suitable metal materials are also applicable to the disclosure. In one embodiment, the appearance profile of the metal portion 18 of the contact 16 may be spherical, but the disclosure is not limited thereto, and other suitable appearance profiles are also applicable to the disclosure. In one embodiment, when the metal portion 18 of the contact 16 is spherical, its particle size is in a range from about 50 μm to about 500 μm, but the disclosure is not limited thereto, and other suitable particle sizes are also applicable to the disclosure. In one embodiment, the insulating portion 20 of the contact 16 may include organic insulating materials, such as epoxy resin, polyimide (PI), benzocyclobutene (BCB), or a combination of the above various organic insulating materials, but the disclosure is not limited thereto, and other suitable organic insulating materials are also applicable to the disclosure.

In FIG. 4, the insulating portion 20 of the contact 16 includes a first portion 20a, a second portion 20b, and a third portion 20c. The first portion 20a is in contact with the circuit layer 14. The third portion 20c is in contact with the carrier 12. The second portion 20b is located between the first portion 20a and the third portion 20c. In one embodiment, the thickness t1 of the first portion 20a, the thickness t2 of the second portion 20b, and the thickness t3 of the third portion 20c of the insulating portion 20 are not all the same. For example, the thickness t1 of the first portion 20a is about the same as or different from the thickness t3 of the third portion 20c, and the thickness t1 of the first portion 20a is approximately greater than the thickness t2 of the second portion 20b. As shown in FIG. 4, when the metal portion 18 of the contact 16 is spherical, the sidewall 20′ of the insulating portion 20 may present, for example, an inwardly concave profile. In one embodiment, the thickness t2 of the second portion 20b of the insulating portion 20 is in a range from about 0.1 μm to about 100 μm. In the embodiment shown in FIG. 4, the insulating portion 20 of each contact 16 is located on the periphery of its own metal portion 18. That is, the insulating portions 20 of the adjacent contacts 16 are separated from each other by the gap 22 and are not substantially in contact with each other, or the insulating portions 20 of the adjacent contacts 16 are in contact with each other via the gap 22.

In one embodiment, the semiconductor package structure 10 of the disclosure further includes a chip 24 disposed on the circuit layer 14 and electrically connected to the circuit layer 14. The chip 24 may be electrically connected to the carrier 12 through the circuit layer 14 and the contacts 16.

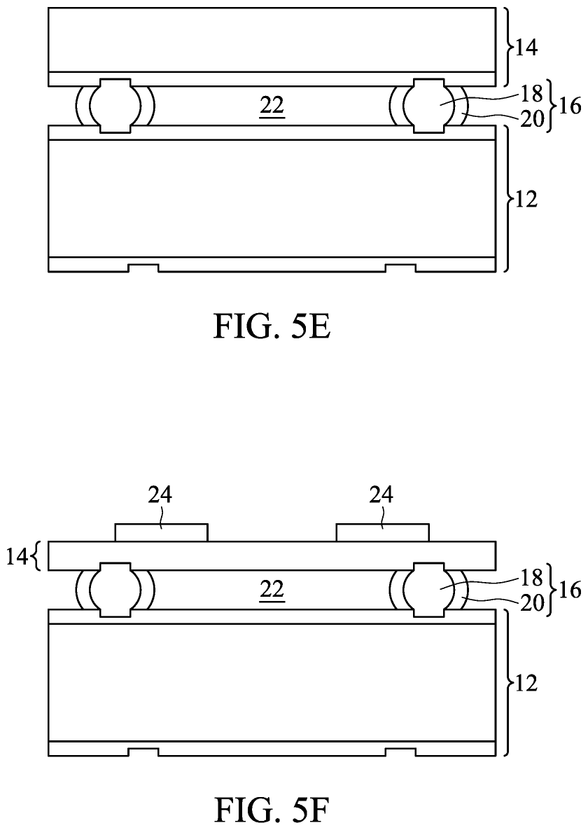

Referring to FIGS. 5A-5F, in accordance with one embodiment of the disclosure, a method for fabricating a semiconductor package structure is provided. FIGS. 5A-5F show cross-sectional views of the method for fabricating a semiconductor package structure.

As shown in FIG. 5A, a carrier 12 is provided, on which a first metal pad 26 is disposed. In one embodiment, the first metal pad 26 may include tin, silver, copper, nickel, germanium, lead, antimony, bismuth, cadmium, gold, indium, aluminum, arsenic, iron, zinc, or an alloy combination of the above various metal materials, but the disclosure is not limited thereto, and other suitable metal materials are also applicable to the disclosure. In one embodiment, the appearance profile of the first metal pad 26 may be hemispherical, but the disclosure is not limited thereto, and other suitable appearance profiles are also applicable to the disclosure. In one embodiment, when the first metal pad 26 is hemispherical, its particle size is in a range from about 50 μm to about 500 μm, but the disclosure is not limited thereto, and other suitable particle sizes are also applicable to the disclosure.

As shown in FIG. 5B, a substrate 28 with a flat surface is provided, on which a circuit layer 14 and a second metal pad 30 are disposed in sequence. In one embodiment, the substrate 28 may include a glass substrate, but the disclosure is not limited thereto, and other suitable substrate materials are also applicable to the disclosure. In one embodiment, the second metal pad 30 may include tin, silver, copper, nickel, germanium, lead, antimony, bismuth, cadmium, gold, indium, aluminum, arsenic, iron, zinc, or an alloy combination of the above various metal materials, but the disclosure is not limited thereto, and other suitable metal materials are also applicable to the disclosure. In one embodiment, the appearance profile of the second metal pad 30 may be hemispherical, but the disclosure is not limited thereto, and other suitable appearance profiles are also applicable to the disclosure. In one embodiment, when the second metal pad 30 is hemispherical, its particle size is in a range from about 50 μm to about 500 μm, but the disclosure is not limited thereto, and other suitable particle sizes are also applicable to the disclosure.

As shown in FIG. 5C, a contact material 32 is formed on the first metal pad 26 of the carrier 12. In the embodiment shown in FIG. 5C, the method of forming the contact material 32 includes that a metal material 34 is first formed on the first metal pad 26 of the carrier 12, and then an insulating material 36 is formed on the metal material 34. In one embodiment, the method (not shown) of forming the contact material 32 includes that a hybrid material is directly formed on the first metal pad 26 of the carrier 12. The hybrid material includes a mixture of the metal material 34 and the insulating material 36. In one embodiment, the contact material 32 (including the metal material 34 and the insulating material 36) may be formed on the first metal pad 26 of the carrier 12 by, for example, a stencil printing process.

As shown in FIG. 5D, the circuit layer 14 is bonded to the carrier 12 by a reflow process 38 to form a plurality of contacts 16 between the circuit layer 14 and the carrier 12. Each contact 16 includes a metal portion 18 and an insulating portion 20. The insulating portion 20 surrounds the metal portion 18. A gap 22 is formed between adjacent contacts 16. In the embodiment shown in FIG. 5D, the first metal pad 26, the second metal pad 30, and the metal material 34 form the metal portion 18 of the contact 16. The insulating material 36 forms the insulating portion 20 of the contact 16. That is, the circuit layer 14 is bonded to the carrier 12 through the second metal pad 30, the contact material 32, and the first metal pad 26.

According to FIGS. 1-4, in the contact 16, the profile of the insulating portion 20 surrounding the metal portion 18 includes outward protrusion, perpendicular to the carrier and the circuit layer, and inward concave, etc., but the disclosure is not limited thereto, and other suitable profiles are also applicable to the disclosure. In the disclosure, the profile of the insulating portion 20 depends, for example, on the amount of the insulating material used, the cohesive force of the contact material itself, the adhesion force between the contact material and the interface, gravity, and other external factors.

In addition, due to the sufficient spacing between the positions where the contacts are intended to be formed and the appropriate amount of insulating material used, when the insulating material whose flow behavior obeys the capillary phenomenon is subjected to the reflow process, the insulating material of adjacent contacts will not be bonded to each other due to the excessive outward extension of the insulating material, so that the appropriate size of the gap between the contacts can still be maintained.

As shown in FIG. 5E, the substrate 28 is removed.

As shown in FIG. 5F, a chip 24 is formed on the circuit layer 14. So far, the fabrication of the semiconductor package structure of the disclosure is completed.

### Comparative Example 1

### Test of Warpage Degree and Stress Value of Traditional Semiconductor Package Structure

In this comparative example, the test of the warpage degree and stress value of the traditional semiconductor package structure (i.e. the contacts that electrically connect the circuit layer and the carrier are not covered with the insulating material) is performed, and the test results are as follows.

Warpage degree: the warpage value of the overall semiconductor package structure is 41.6 μm, and the warpage value of the circuit layer is 19.5 μm.

Stress value: 60.8 MPa

### Comparative Example 2

### Test of Warpage Degree and Stress Value of Traditional Semiconductor Package Structure

In this comparative example, the test of the warpage degree and stress value of the traditional semiconductor package structure (i.e. the insulating material covers the contacts and fills the gaps between the circuit layer and the carrier) is performed, and the test results are as follows.

Warpage degree: the warpage value of the overall semiconductor package structure is 203 μm, and the warpage value of the circuit layer is 131.7 μm.

Stress value: 12.9 MPa

### Example 1

### Test of Warpage Degree and Stress Value of Semiconductor Package Structure of the Disclosure

In this example, the test of the warpage degree and stress value of the present semiconductor package structure (i.e. the insulating material merely covers the contacts, and the gap is left between the adjacent contacts) is performed, and the test results are as follows.

Warpage degree: the warpage value of the overall semiconductor package structure is 55.9 μm, and the warpage value of the circuit layer is 31.2 μm.

Stress value: 39.5 MPa

From the test results of the above comparative examples and example, it can be seen that, in Comparative Example 1, although the warpage degree of the semiconductor package structure (i.e. the contacts are not covered with the insulating material) is relatively low, its stress value is as high as 60.8 MPa, which will affect the reliability and durability of subsequent products. In Comparative Example 2, although the stress value of the semiconductor package structure (i.e. the insulating material covers the contacts and fills the gaps between the circuit layer and the carrier) is 12.9 MPa, the warpage values of the overall structure and the circuit layer are increased significantly, which will seriously affect the bonding quality between the circuit layer and the carrier and the application of subsequent products. In Example 1, the warpage degree and stress value of the present semiconductor package structure (i.e. the insulating material covers the contacts, and the gap is left between the adjacent contacts) are maintained in an appropriate range. Also, when the reliability analysis is carried out by the thermal cycling test (TCT) at the temperature from −55° C. to 120° C., the semiconductor package structure of the disclosure can reach more than 4,000 cycles.

The disclosure aims to establish a specific composite connection structure (that is, the insulating material merely covers the contacts which are used to connect the circuit layer and the carrier, and there are still gaps between the adjacent contacts) to reduce the warping and deformation caused by the difference in thermal deformation between heterogeneous structures, and at the same time, to improve the reliability of products.

The disclosure is a board-level heterogeneous integration with expandability and high-flexibility design. Through the thin-film transfer technology, the circuit layer with thin lines and high aspect ratio is fabricated into an integrated large-area high-performance carrier including the circuit layer, an IC chip, and a PCB carrier with higher yield and lower cost. The high-level carrier can be expanded to large-area applications, and has better performance in terms of repair, yield, and cost, enhancing competitiveness and advantages. The solutions for advanced carriers for next-generation high-performance computing can be found.

Although some embodiments of the disclosure and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and operations described in the specification. As one of ordinary skill in the art will readily appreciate from the disclosure of the present disclosure, processes, machines, manufacture, compositions of matter, means, methods, or operations, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or operations.

What is claimed is:

1. A semiconductor package structure, comprising:
a carrier;
a circuit layer; and
a plurality of contacts electrically connecting the circuit layer to the carrier, wherein each contact comprises a metal portion and an insulating portion surrounding the metal portion, and a gap is formed between the contacts.

2. The semiconductor package structure as claimed in claim 1, wherein the carrier comprises a substrate or a printed circuit board (PCB).

3. The semiconductor package structure as claimed in claim 1, wherein the circuit layer has a line width or a line spacing less than 15 μm.

4. The semiconductor package structure as claimed in claim 1, wherein the circuit layer comprises a redistribution layer (RDL).

5. The semiconductor package structure as claimed in claim 1, wherein the metal portion comprises tin, silver, copper, nickel, germanium, lead, antimony, bismuth, cadmium, gold, indium, aluminum, arsenic, iron, zinc, or a combination thereof.

6. The semiconductor package structure as claimed in claim 1, wherein the insulating portion comprises epoxy resin.

7. The semiconductor package structure as claimed in claim 1, wherein the insulating portion comprises a first portion having a thickness, a second portion having a thickness and a third portion having a thickness, the first portion is in contact with the circuit layer, the third portion is in contact with the carrier, and the second portion is located between the first portion and the third portion.

8. The semiconductor package structure as claimed in claim 7, wherein the thickness of the first portion, the thickness of the second portion, and the thickness of 2 the third portion are the same.

9. The semiconductor package structure as claimed in claim 7, wherein the thickness of the first portion is the same as that of the third portion, and the thickness 2 of the first portion is greater than that of the second portion.

10. The semiconductor package structure as claimed in claim 7, wherein the thickness of the second portion is in a range from 0.1 μm to 100 μm.

11. The semiconductor package structure as claimed in claim 1, further comprising a chip disposed on the circuit layer.

12. A method for fabricating a semiconductor package structure, comprising:
providing a carrier on which a first metal pad is disposed;
providing a substrate on which a circuit layer and a second metal pad are disposed;
forming a contact material on the first metal pad of the carrier;
bonding the circuit layer to the carrier through the second metal pad, the contact material, and the first metal pad; and
removing the substrate.

13. The method for fabricating a semiconductor package structure as claimed in claim 12, wherein the method of forming the contact material comprises forming a hybrid material comprising a metal material and an insulating material on the first metal pad of the carrier.

14. The method for fabricating a semiconductor package structure as claimed in claim 12, wherein the method of forming the contact material comprises forming a metal material on the first metal pad of the carrier, and then forming an insulating material on the metal material.

15. The method for fabricating a semiconductor package structure as claimed in claim 12, wherein the contact material is formed on the first metal pad of the carrier by a stencil printing process.

16. The method for fabricating a semiconductor package structure as claimed in claim 12, wherein the circuit layer is bonded to the carrier by a reflow process to form a plurality of contacts between the circuit layer and the carrier, wherein each contact comprises a metal portion and an insulating portion surrounding the metal portion, and a gap is formed between the contacts.

17. The method for fabricating a semiconductor package structure as claimed in claim 12, further comprising forming a chip on the circuit layer.
